(19) United States
(12) Patent Application Publication
(10) Pub. No.: US 2025/0366285 A1
(43) Pub. Date: Nov. 27, 2025

(54) CIRCUIT SUBSTRATE AND DISPLAY DEVICE

(71) Applicant: AUO Corporation, Hsinchu City (TW)

(72) Inventors: Han-Chung Lai, Hsinchu City (TW); Ta-Wen Liao, Hsinchu City (TW); Tai-Tso Lin, Hsinchu City (TW); I-Peng Chien, Hsinchu City (TW); Cheng-Min Lu, Hsinchu City (TW); Chen-Yuan Tu, Hsinchu City (TW)

(73) Assignee: AUO Corporation, Hsinchu City (TW)

(21) Appl. No.: 18/976,388

(22) Filed: Dec. 11, 2024

(30) Foreign Application Priority Data
May 22, 2024 (TW) 113118922

(51) Int. Cl. H10H 29/24; H01L 25/075; H10H 29/01

(52) U.S. Cl. CPC H10H 29/24; H01L 25/0753; H10H 29/01

(57) ABSTRACT

A circuit substrate including multiple display units is provided. Each of the display units includes at least one first sub-unit and at least one second sub-unit. Each of the first sub-units includes at least one first pad, and each of the second sub-units includes at least one second pad. A first protection layer is disposed on the first pad. The first protection layer and a second protection layer are disposed on the second pad. The first protection layer is disposed between the second pad and the second protection layer. There is a space suitable for accommodating a light emitting diode above the first pad and the second pad respectively. A display device is also provided.

### CROSS-REFERENCE TO RELATED APPLICATION

This application claims the priority benefit of Taiwan application serial no. 113118922, filed on May 22, 2024. The entirety of the above-mentioned patent application is hereby incorporated by reference herein and made a part of this specification.

### BACKGROUND

### Technical Field

The disclosure relates to a circuit substrate and a display device.

### Description of Related Art

A circuit substrate used to drive a light emitting element has multiple metal pads, such as copper pads. The copper pads are prone to oxidation. In some conventional technologies, a tungsten alloy is disposed on the copper pad as a protection layer. However, when intermetallic bonding is to be performed on the copper pad with the tungsten alloy thereon and a tin pin of the light emitting element, a bonding yield is likely to be low. In order to improve an intermetallic bonding yield of the interface, it is necessary to increase energy of a bonding process, but this will easily cause damage to a display device and the circuit substrate.

### SUMMARY

The disclosure provides a circuit substrate and a display device, in which a pad on the circuit substrate is protected by a protection layer to avoid oxidation, and the protection layer may be removed before the pad and a light emitting element are bonded, so as to improve a bonding yield.

According to an embodiment of the disclosure, a circuit substrate is provided, including multiple display units. Each of the display units includes at least one first sub-unit and at least one second sub-unit. Each of the first sub-unit includes at least one first pad, and each of the second sub-unit includes at least one second pad. The first pad is provided with a first protection layer, and the second pad is provided with the first protection layer and a second protection layer. The first protection layer is disposed between the second pad and the second protection layer. There are spaces suitable for accommodating a light emitting diode above the first pad and the second pad respectively.

According to another embodiment of the disclosure, a display device is provided, including multiple display units. Each of the display units includes at least one first sub-unit and at least one second sub-unit. Each of the first sub-unit includes at least one first pad, and each of the second sub-unit includes at least one second pad. The second pad is provided with a first protection layer and a second protection layer. The first protection layer is disposed between the second pad and the second protection layer, and the first pad is provided with a light emitting diode.

According to still another embodiment of the disclosure, a display device is provided, including multiple display units. Each of the display units includes at least one first sub-unit and at least one second sub-unit. Each of the first sub-unit includes at least one first pad, and each of the second sub-unit includes at least one second pad. The second pad is provided with a protection layer. The first pad is provided with a light emitting diode. There is a space suitable for accommodating the light emitting diode above the second pad, and the protection layer includes metal oxide, and an oxide semiconductor and nitride thereof.

Based on the above, compared to the conventional technology, in the embodiment of the disclosure, the second sub-unit is additionally disposed on the circuit substrate, the pad is disposed on the second sub-unit, and the first protection layer and the second protection layer are disposed on the pad to protect the pad. Accordingly, when the circuit substrate is used to manufacture a display device, and the light emitting diode of the display device is damaged, the pad may be used to dispose another light emitting diode to improve a yield of the display device. The pad is protected by the protection layers to avoid oxidation, and the protection layers may be removed before the pad and the light emitting diode are bonded to improve a bonding yield.

In order for the aforementioned features and advantages of the disclosure to be more comprehensible, embodiments accompanied with drawings are described in detail below.

### BRIEF DESCRIPTION OF THE DRAWINGS

FIG. 1A is a schematic view of a display device according to some embodiments of the disclosure.

FIGS. 1B to 1G are schematic views of a display unit according to some embodiments of the disclosure.

FIGS. 2A to 2F illustrate a manufacturing method of a display device according to an embodiment of the disclosure.

FIGS. 3A to 3F illustrate a manufacturing method of a display device according to an embodiment of the disclosure.

FIGS. 4A to 4F illustrate a manufacturing method of a display device according to an embodiment of the disclosure.

FIGS. 5A to 5F illustrate a manufacturing method of a display device according to an embodiment of the disclosure.

FIGS. 6A to 6F illustrate a manufacturing method of a display device according to an embodiment of the disclosure.

FIGS. 7A to 7F illustrate a manufacturing method of a display device according to an embodiment of the disclosure.

FIGS. 8A to 8F illustrate a manufacturing method of a display device according to an embodiment of the disclosure.

FIGS. 9A to 9F illustrate a manufacturing method of a display device according to an embodiment of the disclosure.

### DETAILED DESCRIPTION OF DISCLOSED EMBODIMENTS

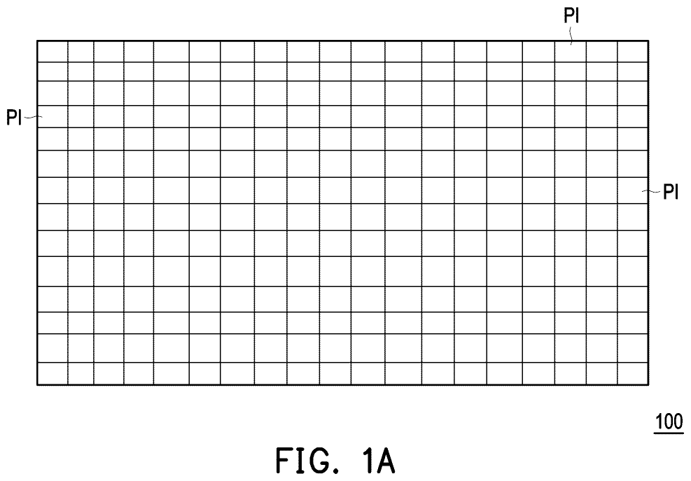

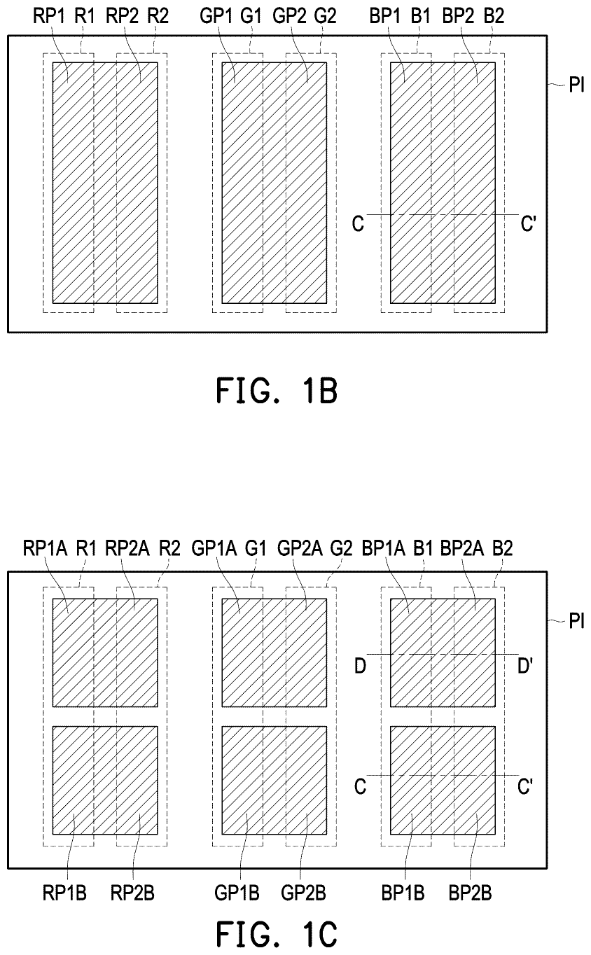

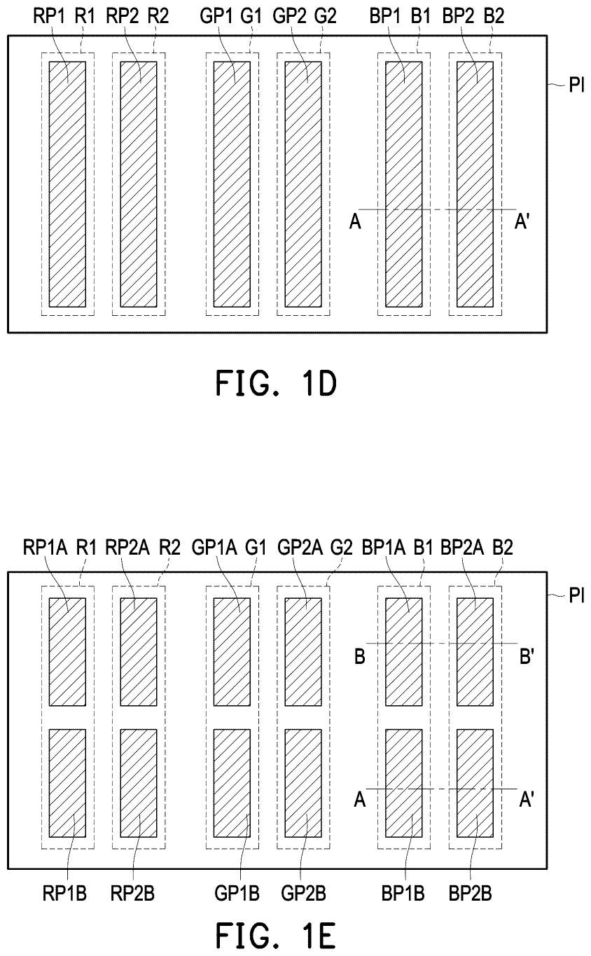

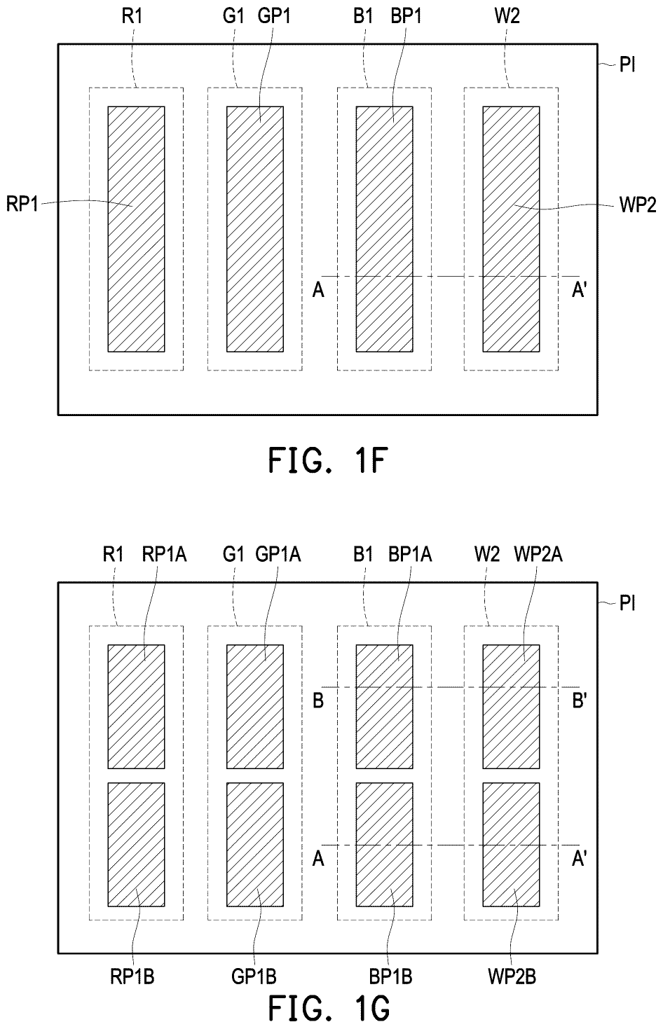

Referring to FIG. 1A, FIG. 1A is a schematic view of a display device according to some embodiments of the disclosure. A display device 100 includes multiple display units PI disposed in an array.

Referring to FIGS. 1A and 1B, according to the first embodiment of the disclosure, each of the display units PI in the display device 100 includes three first sub-units R1, G1, and B1 and three second sub-units R2, G2, and B2. The first sub-unit R1 includes a pad RP1. The first sub-unit G1 includes a pad GP1. The first sub-unit B1 includes a pad BP1. The second sub-unit R2 includes a pad RP2. The second sub-unit G2 includes a pad GP2. The second sub-unit B2 includes a pad BP2. In addition, the pad RP1 and the pad RP2 are disposed integrally. The pad GP1 and the pad GP2 are disposed integrally. The pad BP1 and the pad BP2 are disposed integrally.

Referring to FIGS. 1A and 1C, according to the second embodiment of the disclosure, each of the display units PI in the display device 100 includes the three first sub-units R1, G1, and B1 and the three second sub-units R2, G2, and B2. The first sub-unit R1 includes a pad RP1A and a pad RP1B. The first sub-unit G1 includes a pad GP1A and a pad GP1B. The first sub-unit B1 includes a pad BP1A and a pad BP1B. The second sub-unit R2 includes a pad RP2A and a pad RP2B. The second sub-unit G2 includes a pad GP2A and a pad GP2B. The second sub-unit B2 includes a pad BP2A and a pad BP2B. In addition, the pad RP1A and the pad RP2A are disposed integrally. The pad RP1B and the pad RP2B are disposed integrally. The pad GP1A and the pad GP2A are disposed integrally. The pad GP1B and the pad GP2B are disposed integrally. The pad BP1A and the pad BP2A are disposed integrally. The pad BP1B and the pad BP2B are disposed integrally.

Referring to FIGS. 1A and 1D, according to the third embodiment of the disclosure, each of the display units PI in the display device 100 includes the three first sub-units R1, G1, and B1 and the three second sub-units R2, G2, and B2. The first sub-unit R1 includes the pad RP1. The first sub-unit G1 includes the pad GP1. The first sub-unit B1 includes the pad BP1. The second sub-unit R2 includes the pad RP2. The second sub-unit G2 includes the pad GP2. The second sub-unit B2 includes the pad BP2. In addition, the pad RP1 and the pad RP2 are disposed separately. The pad GP1 and the pad GP2 are disposed separately. The pad BP1 and the pad BP2 are disposed separately.

Referring to FIGS. 1A and 1E, according to the fourth embodiment of the disclosure, each of the display units PI in the display device 100 includes the three first sub-units R1, G1, and B1 and the three second sub-units R2, G2, and B2. The first sub-unit R1 includes the pad RP1A and the pad RP1B. The first sub-unit G1 includes the pad GP1A and the pad GP1B. The first sub-unit B1 includes the pad BP1A and the pad BP1B. The second sub-unit R2 includes the pad RP2A and the pad RP2B. The second sub-unit G2 includes the pad GP2A and the pad GP2B. The second sub-unit B2 includes the pad BP2A and the pad BP2B. In addition, the pad RP1A and the pad RP2A are disposed separately. The pad RP1B and the pad RP2B are disposed separately. The pad GP1A and the pad GP2A are disposed separately. The pad GP1B and the pad GP2B are disposed separately. The pad BP1A and the pad BP2A are disposed separately. The pad BP1B and the pad BP2B are disposed separately.

Referring to FIGS. 1A and 1F, according to the fifth embodiment of the disclosure, each of the display units PI in the display device 100 includes the three first sub-units R1, G1, and B1 and one second sub-unit W2. The first sub-unit R1 includes the pad RP1. The first sub-unit G1 includes the pad GP1. The first sub-unit B1 includes the pad BP1. The second sub-unit W2 includes a pad WP2. In this fifth embodiment, the pad RP1, the pad GP1, the pad BP1, and the pad WP2 in each of the display units PI are disposed separately.

Referring to FIGS. 1A and 1G, according to the sixth embodiment of the disclosure, each of the display units PI in the display device 100 includes the three first sub-units R1, G1, and B1 and the one second sub-unit W2. The first sub-unit R1 includes the pad RP1A and the pad RP1B. The first sub-unit G1 includes the pad GP1A and the pad GP1B. The first sub-unit B1 includes the pad BP1A and the pad BP1B. The second sub-unit W2 includes a pad WP2A and a pad WP2B. In this sixth embodiment, the pad RP1A, the pad RP1B, the pad GP1A, the pad GP1B, the pad BP1A, the pad BP1B, the pad WP2A, and the pad WP2B in each of the display units PI are disposed separately.

Next, light emitting diodes respectively connected to the pads in the display device 100 in the first to sixth embodiments will be described.

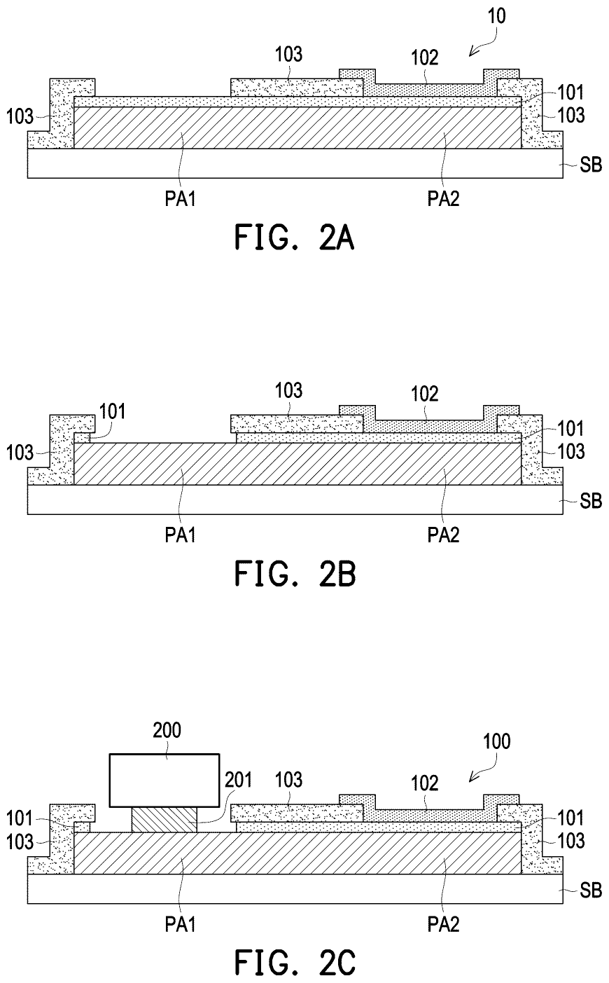

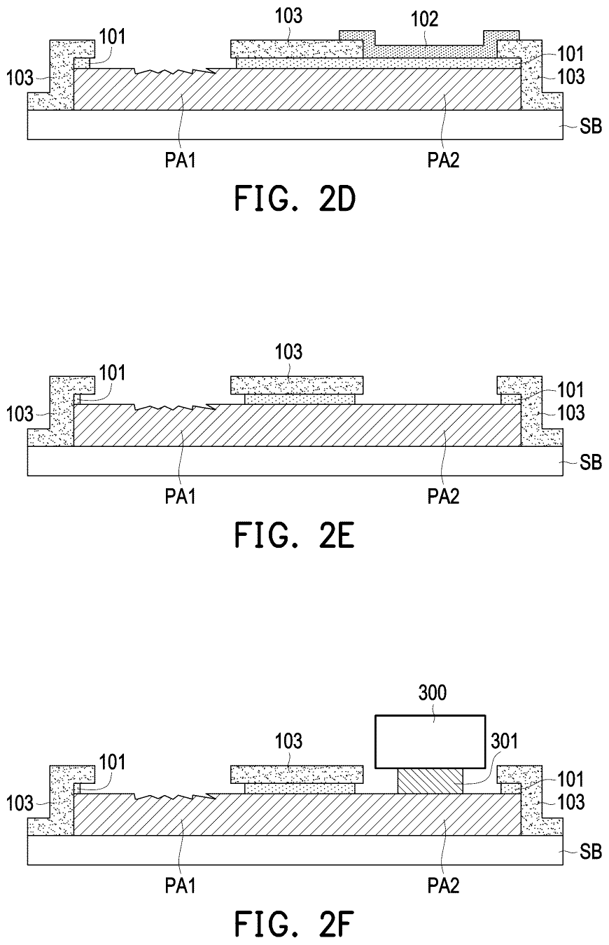

Referring to FIGS. 2A to 2F, FIGS. 2A to 2F illustrate a manufacturing method of the display device shown in FIG. 1B (the first embodiment) and FIG. 1C (the second embodiment) according to an embodiment of the disclosure. Specifically, a first pad PA1 and a second pad PA2 shown in FIGS. 2A to 2F may respectively correspond to the pad RP1 and the pad RP2 in the first embodiment, respectively correspond to the pad GP1 and the pad GP2 in the first embodiment, and respectively correspond to the pad BP1 and the pad BP2 in the first embodiment (FIG. 2A may be regarded as a cross section of a line segment CC′ shown in FIG. 1B). Similarly, the first pad PA1 and the second pad PA2 shown in FIGS. 2A to 2F may also respectively correspond to the pad RP1A and the pad RP2A in the second embodiment, respectively correspond to the pad RP1B and the pad RP2B in the second embodiment, respectively correspond to the pad GP1A and the pad GP2A in the second embodiment, respectively correspond to the pad GP1B and the pad GP2B in the second embodiment, respectively correspond to the pad BP1A and the pad BP2A in the second embodiment (FIG. 2A may be regarded as a cross section of a line segment DD′ shown in FIG. 1C), and respectively correspond to the pad BP1B and the pad BP2B in the second embodiment (FIG. 2A may be regarded as the cross section of the line segment CC′ shown in FIG. 1C).

Referring to FIG. 2A, the manufacturing method of the display device according to this embodiment includes the following. The first pad PA1 and the second pad PA2 that are integrally formed are disposed on a substrate SB, and a first protection layer 101 and an insulating layer 103 are sequentially disposed on the first pad PA1 and the second pad PA2. Portions of the first protection layer 101 corresponding to the first pad PA1 and the second pad PA2 are exposed from the insulating layer 103. In addition, a second protection layer 102 is disposed on the portion of the first protection layer 101 corresponding to the second pad PA2. According to the above process steps, a circuit substrate 10 is formed. It should be noted that there are spaces suitable for accommodating the light emitting diodes above the first pad PA1 and the second pad PA2 respectively.

Referring to FIG. 2B, in this step, the portion of the first protection layer 101 corresponding to the first pad PA1 is removed. Accordingly, at least a portion of the first pad PA1 is exposed. It should be noted that there may be a portion of the first protection layer 101 that has not been removed between the first pad PA1 and the insulating layer 103, as shown in FIG. 2B.

In some embodiments, the first protection layer 101 may include a tungsten (W) alloy, such as WNi, WNiCu, WNiMo, and WNiMo, or the first protection layer 101 may include a titanium (Ti) alloy. In these embodiments, the portion of the first protection layer 101 corresponding to the first pad PA1 may be removed by a wet etching process. The above wet etching may be performed with water, an acid etching solution (e.g., oxalic acid), or an aqueous solution with a pH value greater than 4.

In some embodiments, the first protection layer 101 may include metal titanium (Ti), metal molybdenum (Mo), and an alloy thereof of MoTa. In these embodiments, the portion of the first protection layer 101 corresponding to the first pad PA1 may be removed by a dry etching process. The above dry etching may be performed with gases of BCl₃ and Cl₂ or SF₆ and O₂.

In some embodiments, the first protection layer 101 may include nitride of the tungsten (W) alloy, such as WNiNₓ. In these embodiments, the portion of the first protection layer 101 corresponding to the first pad PA1 may be removed by the wet etching process. The above wet etching may be performed with the water, the acid etching solution (e.g., oxalic acid), or the aqueous solution with the pH value greater than 4.

In some embodiments, the first protection layer 101 may include metal nitride or metal oxide, such as MoNₓ. In these embodiments, the portion of the first protection layer 101 corresponding to the first pad PA1 may be removed by the dry etching process. The above dry etching may be performed with the gases of BCl₃ and Cl₂ or SF₆ and O₂.

In some embodiments, the first protection layer 101 may include metal oxide, such as IZO and AZO, or the first protection layer 101 may include a semiconductor, such as IGZO and ITZO. In these embodiments, the portion of the first protection layer 101 corresponding to the first pad PA1 may be removed by the wet etching process. The above wet etching may be performed with the acid etching solution (e.g., oxalic acid).

Referring to FIG. 2C, in this step, a light emitting diode 200 is disposed on the exposed first pad PA1, thereby completing the display device 100. It should be noted that there is a space suitable for accommodating the light emitting diode 200 above the second pad PA2.

Specifically, referring to FIGS. 1A, 1B, and 2C together, in the first embodiment, the first pad PA1 and the second pad PA2 in FIG. 2C respectively refer to the pad RP1 and the pad RP2 in FIG. 1B, and the light emitting diode 200 in FIG. 2C is a vertical red LED. The first pad PA1 and the second pad PA2 in FIG. 2C also respectively refer to the pad GP1 and the pad GP2 in FIG. 1B, and the light emitting diode 200 is a vertical green LED. The first pad PA1 and the second pad PA2 in FIG. 2C also respectively refer to the pad BP1 and the pad BP2 in FIG. 1B, and the light emitting diode 200 is a vertical blue LED. In other words, in the first embodiment shown in FIGS. 1A and 1B, the vertical red LED, the vertical green LED, and the vertical blue LED are respectively disposed on the three first sub-units R1, G1, and B1 of each of the display units PI in the display device 100.

On the other hand, referring to FIGS. 1A, 1C, and 2C together, in the second embodiment, the first pad PA1 and the second pad PA2 in FIG. 2C respectively refer to the pad RP1A and the pad RP2A in FIG. 1C and also respectively refer to the pad RP1B and the pad RP2B in FIG. 1C, and the light emitting diode 200 in FIG. 2C is a flip-chip red LED. A positive electrode of the flip-chip red LED is connected to one of the pad RP1A and the pad RP1B, and a negative electrode of the flip-chip red LED is connected to the other of the pad RP1A and the pad RP1B. The first pad PA1 and the second pad PA2 in FIG. 2C also respectively refer to the pad GP1A and the pad GP2A in FIG. 1C and also respectively refer to the pad GP1B and the pad GP2B in FIG. 1C, and the light emitting diode 200 in FIG. 2C is a flip-chip green LED. A positive electrode of the flip-chip green LED is connected to one of the pad GP1A and the pad GP1B, and a negative electrode of the flip-chip green LED is connected to the other of the pad GP1A and pad the GP1B. The first pad PA1 and the second pad PA2 in FIG. 2C also respectively refer to the pad BP1A and the pad BP2A in FIG. 1C and also respectively refer to the pad BP1B and the pad BP2B in FIG. 1C, and the light emitting diode 200 in FIG. 2C is a flip-chip blue LED. A positive electrode of the flip-chip blue LED is connected to one of the pad BP1A and the pad BP1B, and a negative electrode of the flip-chip blue LED is connected to the other of the pad BP1A and the pad BP1B. In other words, in the second embodiment shown in FIGS. 1A and 1C, the flip-chip red LED, the flip-chip green LED, and the flip-chip blue LED are respectively disposed on the three first sub-units R1, G1, and B1 of each of the display units PI in the display device 100.

Continuing to refer to FIGS. 2D to 2F, if the light emitting diode 200 is damaged, the light emitting diode 200 may be removed (as shown in FIG. 2D), the second protection layer 102 and the first protection layer 101 on the second pad PA2 are removed sequentially (as shown in the FIGS. 2D and 2E), and a light emitting diode 300 emitting the same color light as the light emitting diode 200 is disposed on the second pad PA2 (as shown in FIG. 2F). A material and an applicable removal method of the first protection layer 101 are as mentioned above. Therefore, the same details will not be repeated in the following.

In some embodiments, the second protection layer 102 may include metal oxide, such as IZO and AZO, or the second protection layer 102 may include an oxide semiconductor and nitride thereof, such as IGZO, ITZO, and IGZON. In these embodiments, the second protection layer 102 may be removed with the acid etching solution (e.g., oxalic acid).

Corresponding to a process of replacing the damaged light emitting diode 200 shown in FIGS. 2D to 2F, in the first embodiment (referring to FIG. 1B), if the vertical red LED on the first sub-unit R1 is damaged, it may be removed, and another vertical red LED may be disposed on the second sub-unit R2; if the vertical green LED on the first sub-unit G1 is damaged, it may be removed, and another vertical green LED may be disposed on the second sub-unit G2; if the vertical blue LED on the first sub-unit B1 is damaged, it may be removed. And another vertical blue LED may be disposed on the second sub-unit B2, so as to complete the replacement of the damaged light emitting diode.

In the second embodiment (referring to FIG. 1C), if the flip-chip red LED connected to the pad RP1A and the pad RP1B on the first sub-unit R1 is damaged, it may be removed, and another flip-chip red LED connected to the pad RP2A and the pad RP2B may be disposed on the second sub-unit R2; if the flip-chip green LED connected to the pad GP1A and the pad GP1B on the first sub-unit G1 is damaged, it may be removed, and another flip-chip green LED connected to the pad GP2A and the pad GP2B may be disposed on the second sub-unit G2; if the flip-chip blue LED connected to the pad BP1A and the pad BP1B on the first sub-unit B1 is damaged, it may be removed, and another flip-chip blue LED connected to the pad BP2A and the pad BP2B may be disposed on the second sub-unit B2, so as to complete the replacement of the damaged light emitting diode.

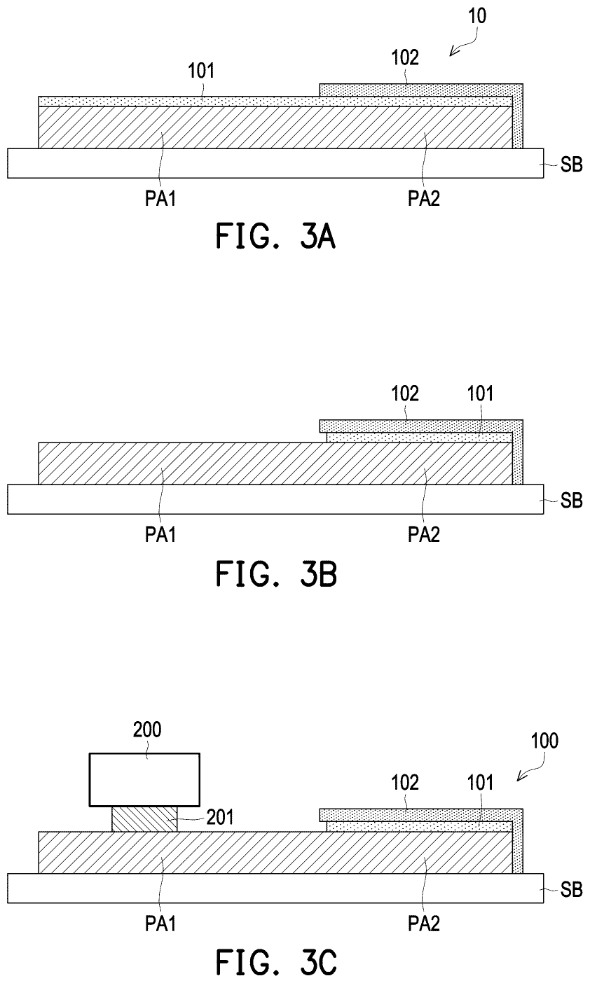

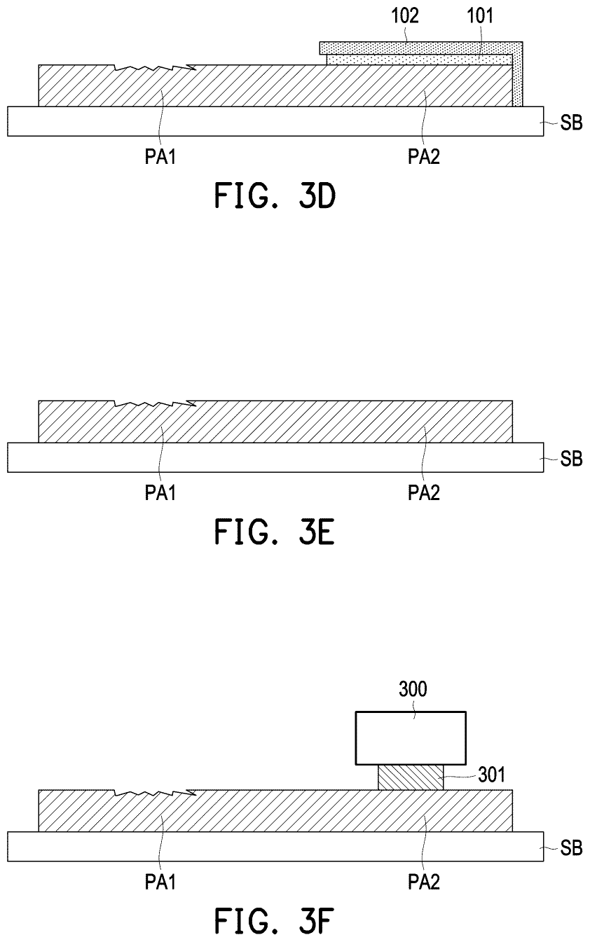

Referring to FIGS. 3A to 3F, FIGS. 3A to 3F illustrate a manufacturing method of the display device shown in FIG. 1B (the first embodiment) and FIG. 1C (the second embodiment) according to an embodiment of the disclosure. It should be noted that a corresponding relationship between the first pad PA1 and the second pad PA2 in FIGS. 3A to 3F and each of the pads in FIGS. 1B and 1C is the same as a corresponding relationship described in the embodiment shown in FIGS. 2A to 2F. Therefore, the same details will not be repeated in this embodiment.

Referring to FIG. 3A, the manufacturing method of the display device according to this embodiment includes the following. The first pad PA1 and the second pad PA2 that are integrally formed are disposed on the substrate SB. The first protection layer 101 is disposed on the first pad PA1 and the second pad PA2. The second protection layer 102 is disposed on the portion of the first protection layer 101 corresponding to the second pad PA2. According to the above process steps, the circuit substrate 10 is formed. In addition, there are spaces suitable for accommodating the light emitting diodes above the first pad PA1 and the second pad PA2 respectively.

Referring to FIG. 3B, in this step, a portion of the first protection layer 101 on which the second protection layer 102 is not disposed is removed. Accordingly, at least a portion of the first pad PA1 is exposed. Here, the material and the applicable removal method of the first protection layer 101 are the same as those described in the embodiment shown in FIGS. 2A to 2F. Therefore, the same details will not be repeated in the following.

Referring to FIG. 3C, in this step, the light emitting diode 200 is disposed on the exposed first pad PA1, thereby completing the display device 100. It should be noted that there is a space suitable for accommodating the light emitting diode 200 above the second pad PA2.

Continuing to refer to FIGS. 3D to 3F, if the light emitting diode 200 is damaged, the light emitting diode 200 may be removed (as shown in FIG. 3D), the second protection layer 102 and the first protection layer 101 on the second pad PA2 may be removed sequentially (as shown in FIGS. 3D and 3E), and the light emitting diode 300 emitting the same color light as the light emitting diode 200 is disposed on the second pad PA2 (as shown in FIG. 3F). Here, the materials and the applicable removal methods of the first protection layer 101 and the second protection layer 102 are the same as those described in the embodiment shown in FIGS. 2A to 2F. Therefore, the same details will not be repeated in the following.

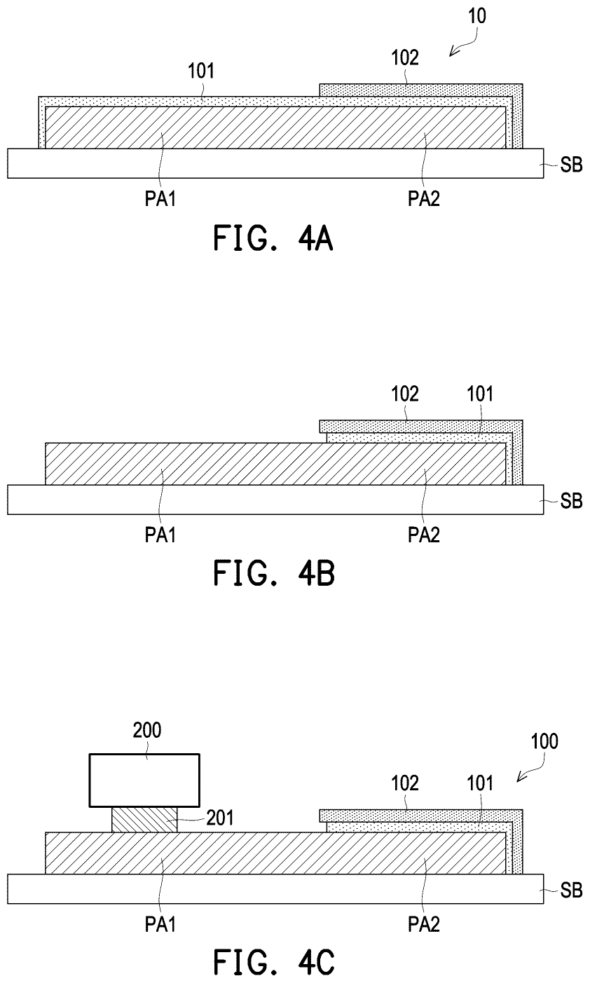

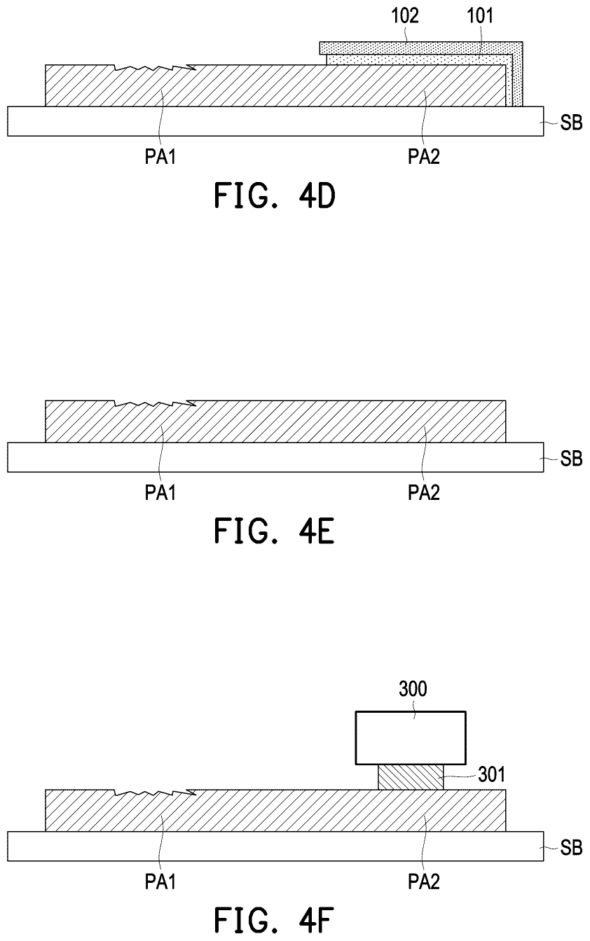

Referring to FIGS. 4A to 4F, FIGS. 4A to 4F illustrate a manufacturing method of the display device shown in FIG. 1B (the first embodiment) and FIG. 1C (the second embodiment) according to an embodiment of the disclosure. It should be noted that a corresponding relationship between the first pad PA1 and the second pad PA2 in FIGS. 4A to 4F and each of the pads in FIGS. 1B and 1C is the same as the corresponding relationship described in the embodiment shown in FIGS. 2A to 2F. Therefore, the same details will not be repeated in this embodiment.

Referring to FIG. 4A, the manufacturing method of the display device according to this embodiment includes the following. The first pad PA1 and the second pad PA2 that are integrally formed are disposed on the substrate SB. The first protection layer 101 is disposed on the first pad PA1 and the second pad PA2. The second protection layer 102 is disposed on the portion of the first protection layer 101 corresponding to the second pad PA2. According to the above process steps, the circuit substrate 10 is formed. In addition, there are spaces suitable for accommodating the light emitting diodes above the first pad PA1 and the second pad PA2 respectively.

Referring to FIG. 4B, in this step, the portion of the first protection layer 101 on which the second protection layer 102 is not disposed is removed. Accordingly, at least a portion of the first pad PA1 is exposed. Here, the material and the applicable removal method of the first protection layer 101 are the same as those described in the embodiment shown in FIGS. 2A to 2F. Therefore, the same details will not be repeated in the following.

Referring to FIG. 4C, in this step, the light emitting diode 200 is disposed on the exposed first pad PA1, thereby completing the display device 100. It should be noted that there is a space suitable for accommodating the light emitting diode 200 above the second pad PA2.

Continuing to refer to FIGS. 4D to 4F, if the light emitting diode 200 is damaged, the light emitting diode 200 may be removed (as shown in FIG. 4D), the second protection layer 102 and the first protection layer 101 on the second pad PA2 may be removed sequentially (as shown in FIGS. 4D and 4E), and the light emitting diode 300 emitting the same color light as the light emitting diode 200 is disposed on the second pad PA2 (as shown in FIG. 4F). Here, the materials and the applicable removal methods of the first protection layer 101 and the second protection layer 102 are the same as those described in the embodiment shown in FIGS. 2A to 2F. Therefore, the same details will not be repeated in the following.

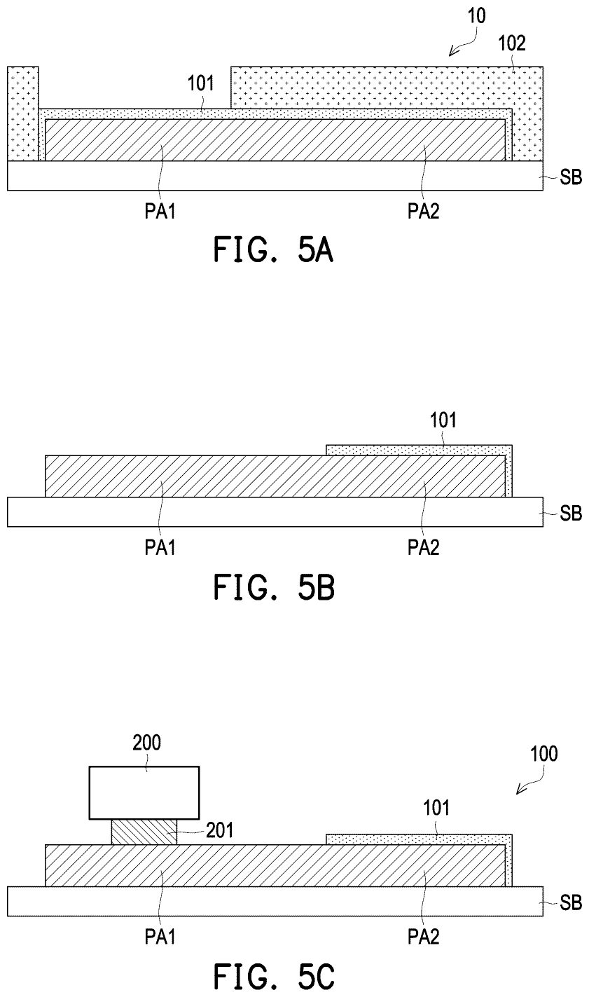

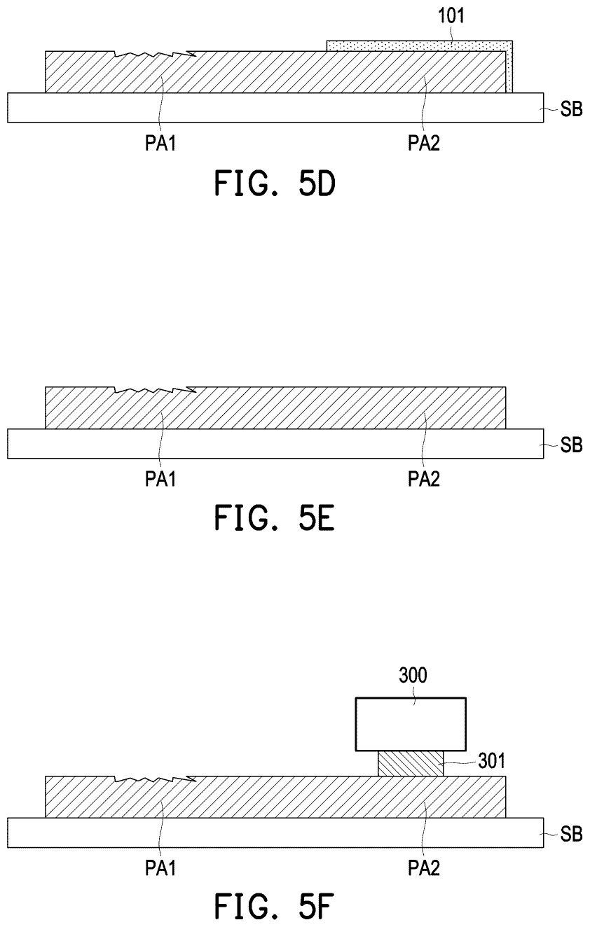

Referring to FIGS. 5A to 5F, FIGS. 5A to 5F illustrate a manufacturing method of the display device shown in FIG. 1B (the first embodiment) and FIG. 1C (the second embodiment) according to an embodiment of the disclosure. It should be noted that a corresponding relationship between the first pad PA1 and the second pad PA2 in FIGS. 5A to 5F and each of the pads in FIGS. 1B and 1C is the same as the corresponding relationship described in the embodiment shown in FIGS. 2A to 2F. Therefore, the same details will not be repeated in this embodiment.

Referring to FIG. 5A, the manufacturing method of the display device according to this embodiment includes the following. The first pad PA1 and the second pad PA2 that are integrally formed are disposed on the substrate SB. The first protection layer 101 is disposed on the first pad PA1 and the second pad PA2. The second protection layer 102 is disposed on the portion of the first protection layer 101 corresponding to the second pad PA2. According to the above process steps, the circuit substrate 10 is formed. In addition, there are spaces suitable for accommodating the light emitting diodes above the first pad PA1 and the second pad PA2 respectively.

Referring to FIG. 5B, in this step, the portion of the first protection layer 101 on which the second protection layer 102 is not disposed is removed. Accordingly, at least a portion of the first pad PA1 is exposed. The second protection layer 102 is also removed. Here, the first protection layer 101 may include metal oxide, such as IZO and AZO, or the first protection layer 101 may include the oxide semiconductor and nitride thereof, such as IGZO, ITZO, and IGZON. In addition, the first protection layer 101 may be removed with the acid etching solution (e.g., oxalic acid). The second protection layer 102 may include an organic photoresist layer, and the second protection layer 102 may be removed with an organic photoresist stripping solution.

Referring to FIG. 5C, in this step, the light emitting diode 200 is disposed on the exposed first pad PA1, thereby completing the display device 100. It should be noted that there is a space suitable for accommodating the light emitting diode 200 above the second pad PA2.

Continuing to refer to FIGS. 5D to 5F, if the light emitting diode 200 is damaged, the light emitting diode 200 may be removed (as shown in FIG. 5D), the first protection layer 101 on the second pad PA2 may be removed (as shown in FIGS. 5D and 5E), and the light emitting diode 300 emitting the same color light as the light emitting diode 200 is disposed on the second pad PA2 (as shown in FIG. 5F).

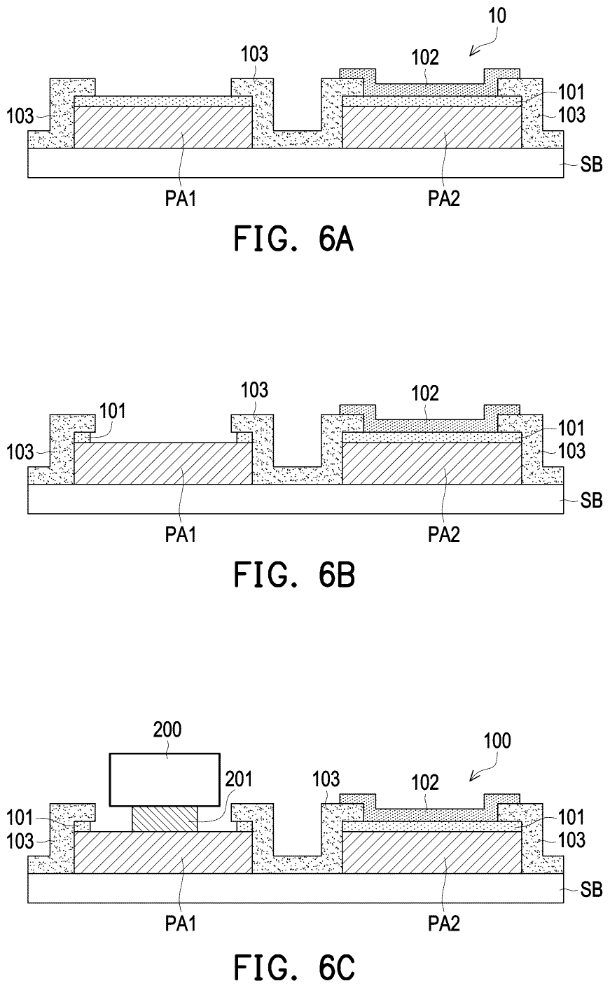

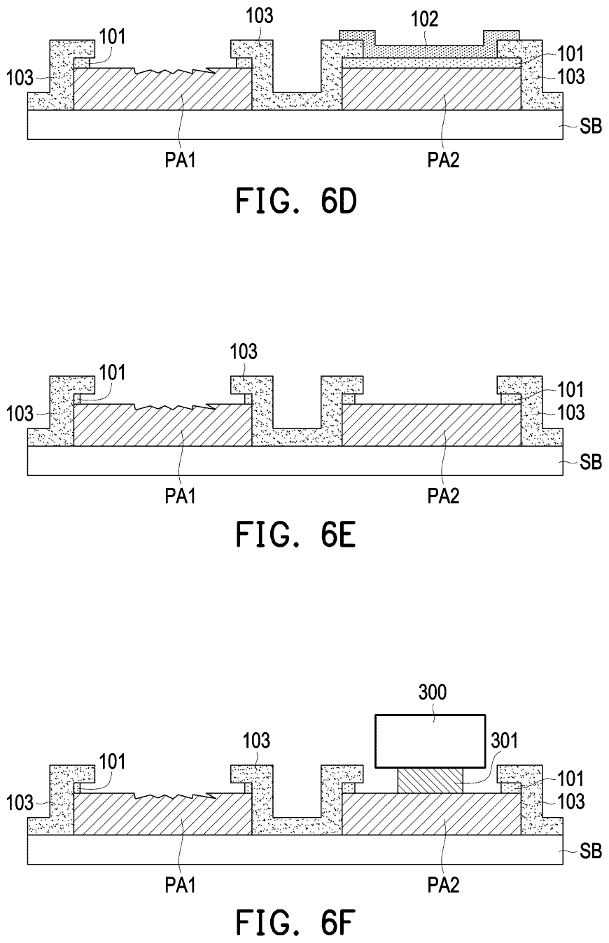

Referring to FIGS. 6A to 6F, FIGS. 6A to 6F illustrate a manufacturing method of the display device shown in FIG. 1D (the third embodiment), FIG. 1E (the fourth embodiment), FIG. 1F (the fifth embodiment), and FIG. 1G (the sixth embodiment) according to an embodiment of the disclosure. It should be noted that the only difference between the embodiment shown in FIGS. 6A to 6F and the embodiment shown in FIGS. 2A to 2F is that in FIGS. 6A to 6F, the first pad PA1 and the second pad PA2 are separate, and in addition to being disposed on the first protection layer 101, the insulating layer 103 is also disposed between the first pad PA1 and the second pad PA2. Therefore, the first pad PA1 and the second pad PA2 shown in FIGS. 6A to 6F may respectively correspond to the pads in the third embodiment, the fourth embodiment, the fifth embodiment, and the sixth embodiment because the pads in these embodiments are separate.

Specifically, the first pad PA1 and the second pad PA2 shown in FIGS. 6A to 6F may respectively correspond to the pad RP1 and the pad RP2 in the third embodiment, respectively correspond to the pad GP1 and the pad GP2 in the third embodiment, and respectively correspond to the pad BP1 and the pad BP2 in the third embodiment (FIG. 6A may be regarded as a cross-section of a line segment AA′ shown in FIG. 1D). Similarly, the first pad PA1 and the second pad PA2 shown in FIGS. 6A to 6F may also respectively correspond to the pad RP1A and the pad RP2A in the fourth embodiment, respectively correspond to the pad RP1B and the pad RP2B in the fourth embodiment, respectively correspond to the pad GP1A and the pad GP2A in the fourth embodiment, respectively correspond to the pad GP1B and the pad GP2B in the fourth embodiment, respectively correspond to the pad BP1A and the pad BP2A in the fourth embodiment (FIG. 6A may be regarded as a cross section of a line segment BB′ shown in FIG. 1E), and respectively correspond to the pad BP1B and the pad BP2B in the fourth embodiment (FIG. 6A may be regarded as the cross section of the line segment AA′ shown in FIG. 1E). Similarly, the first pad PA1 and the second pad PA2 shown in FIGS. 6A to 6F may further respectively correspond to the pad BP1 and the pad WP2 in the fifth embodiment (FIG. 6A may be regarded as the cross section of the line segment AA′ shown in FIG. 1F). Similarly, the first pad PA1 and the second pad PA2 shown in FIGS. 6A to 6F may further respectively correspond to the pad BP1A and the pad WP2A in the sixth embodiment (FIG. 6A may be regarded as the cross section of the line segment BB′ shown in FIG. 1G), and respectively correspond to the pad BP1B and the pad WP2B in the sixth embodiment (FIG. 6A may be regarded as the cross section of the line segment AA′ shown in FIG. 1G).

As mentioned above, the only difference between the embodiment shown in FIGS. 6A to 6F and the embodiment shown in FIGS. 2A to 2F is that in FIGS. 6A to 6F, the first pad PA1 and the second pad PA2 are separate, while in FIGS. 2A to 2F, the first pad PA1 and the second pad PA2 are integrally formed. Therefore, the process steps and materials of each of the layers shown in FIGS. 6A to 6F are substantially the same as the process steps and materials of each of the layers shown in FIGS. 2A to 2F. Therefore, the same details of the process steps and materials of each of the layers in FIGS. 6A to 6F will not be repeated in the following.

It should also be noted that, referring to FIGS. 1A, 1D, and 6C together, in the third embodiment, the first pad PA1 and the second pad PA2 in FIG. 6C respectively refer to the pad RP1 and the pad RP2 in FIG. 1D, and the light emitting diode 200 in FIG. 6C is the vertical red LED. The first pad PA1 and the second pad PA2 in FIG. 6C also respectively refer to the pad GP1 and the pad GP2 in FIG. 1D, and the light emitting diode 200 is the vertical green LED. The first pad PA1 and the second pad PA2 in FIG. 6C also respectively refer to the pad BP1 and the pad BP2 in FIG. 1D, and the light emitting diode 200 is the vertical blue LED. In other words, in the third embodiment shown in FIGS. 1A and 1D, the vertical red LED, the vertical green LED, and the vertical blue LED are respectively disposed on the three first sub-units R1, G1, and B1 of each of the display units PI in the display device 100.

On the other hand, referring to FIGS. 1A, 1E, and 6C together, in the fourth embodiment, the first pad PA1 and the second pad PA2 in FIG. 6C respectively refer to the pad RP1A and the pad RP2A in FIG. 1E and also respectively refer to the pad RP1B and the pad RP2B in FIG. 1E, and the light emitting diode 200 in FIG. 6C is the flip-chip red LED. The positive electrode of the flip-chip red LED is connected to one of the pad RP1A and the pad RP1B, and the negative electrode of the flip-chip red LED is connected to the other of the pad RP1A and the pad RP1B. The first pad PA1 and the second pad PA2 in FIG. 6C also respectively refer to the pad GP1A and the pad GP2A in FIG. 1E and also respectively refer to the pad GP1B and the pad GP2B in FIG. 1E, and the light emitting diode 200 in FIG. 6C is the flip-chip green LED. The positive electrode of the flip-chip green LED is connected to one of the pad GP1A and the pad GP1B, and the negative electrode of the flip-chip green LED is connected to the other of the pad GP1A and the pad GP1B. The first pad PA1 and the second pad PA2 in FIG. 6C also respectively refer to the pad BP1A and the pad BP2A in FIG. 1E and also respectively refer to the pad BP1B and the pad BP2B in FIG. 1E, and the light emitting diode 200 in FIG. 6C is the flip-chip blue LED. The positive electrode of the flip-chip blue LED is connected to one of the pad BP1A and the pad BP1B, and the negative electrode of the flip-chip blue LED is connected to the other of the pad BP1A and the pad BP1B. In other words, in the fourth embodiment shown in FIGS. 1A and 1E, the flip-chip red LED, the flip-chip green LED, and the flip-chip blue LED are respectively disposed on the three first sub-units R1, G1, and B1 of each of the display units PI in the display device 100.

On the other hand, referring to FIGS. 1A, 1F, and 6C together, in the fifth embodiment, the first pad PA1 and the second pad PA2 in FIG. 6C respectively refer to the pad BP1 and the pad WP2 in FIG. 1F, and the light emitting diode 200 in FIG. 6C is the vertical blue LED. In other words, in the fifth embodiment shown in FIGS. 1A and 1F, the vertical blue LED is disposed on the first sub-unit B1 of each of the display units PI in the display device 100. In addition, although not shown in the drawings, in the fifth embodiment shown in FIGS. 1A and 1F, the vertical red LED and the vertical green LED are also respectively disposed on the first sub-units R1 and G1 of each of the display units PI in the display device 100.

On the other hand, referring to FIGS. 1A, 1G, and 6C together, in the sixth embodiment, the first pad PA1 and the second pad PA2 in FIG. 6C respectively refer to the pad BP1A and the pad WP2A in FIG. 1G and also respectively refer to the pad BP1B and the pad WP2B in FIG. 1G, and the light emitting diode 200 in FIG. 6C is the flip-chip blue LED. The positive electrode of the flip-chip blue LED is connected to one of the pad BP1A and the pad BP1B, and the negative electrode of the flip-chip blue LED is connected to the other of the pad BP1A and the pad BP1B. In other words, in the sixth embodiment shown in FIGS. 1A and 1G, the flip-chip blue LED is disposed on the first sub-unit B1 of each of the display units PI in the display device 100. In addition, although not shown in the drawings, in the sixth embodiment shown in FIGS. 1A and 1G, the flip-chip red LED and the flip-chip green LED are also respectively disposed on the first sub-units R1 and G1 of each of the display units PI in the display device 100.

Corresponding to a process of replacing the damaged light emitting diode 200 shown in FIGS. 6D to 6F, in the third embodiment (referring to FIG. 1D), if the vertical red LED on the first sub-unit R1 is damaged, it may be removed, and another vertical red LED may be disposed on the second sub-unit R2; if the vertical green LED on the first sub-unit G1 is damaged, it may be removed, and another vertical green LED may be disposed on the second sub-unit G2; if the vertical blue LED on the first sub-unit B1 is damaged, it may be removed, and another vertical blue LED may be disposed on the second sub-unit B2, so as to complete the replacement of the damaged light emitting diode.

In the fourth embodiment (referring to FIG. 1E), if the flip-chip red LED connected to the pad RP1A and the pad RP1B on the first sub-unit R1 is damaged, it may be removed, and another flip-chip red LED connected to the pad RP2A and the pad RP2B may be disposed on the second sub-unit R2; if the flip-chip green LED connected to the pad GP1A and the pad GP1B on the first sub-unit G1 is damaged, it may be removed, and another flip-chip green LED connected to the pad GP2A and the pad GP2B may be disposed on the second sub-unit G2; if the flip-chip blue LED connected to the pad BP1A and the pad BP1B on the first sub-unit B1 is damaged, it may be removed, and another flip-chip blue LED connected to the pad BP2A and the pad BP2B may be disposed on the second sub-unit B2, so as to complete the replacement of the damaged light emitting diode.

In the fifth embodiment (referring to FIG. 1F), if any one of the vertical red LED on the first sub-unit R1, the vertical green LED on the first sub-unit G1, and the vertical blue LED on the first sub-unit B1 is damaged, it may be removed, and another vertical LED emitting the same color light as the damaged LED may be disposed on the second sub-unit W2, so as to complete the replacement of the damaged light emitting diode.

In the sixth embodiment (referring to FIG. 1G), if any of the flip-chip red LED on the first sub-unit R1, the flip-chip green LED on the first sub-unit G1, and the flip-chip blue LED on the first sub-unit B1 is damaged, it may be removed, and another flip-chip LED emitting the same color light as the damaged LED may be disposed on the second sub-unit W2, so as to complete the replacement of the damaged light emitting diode.

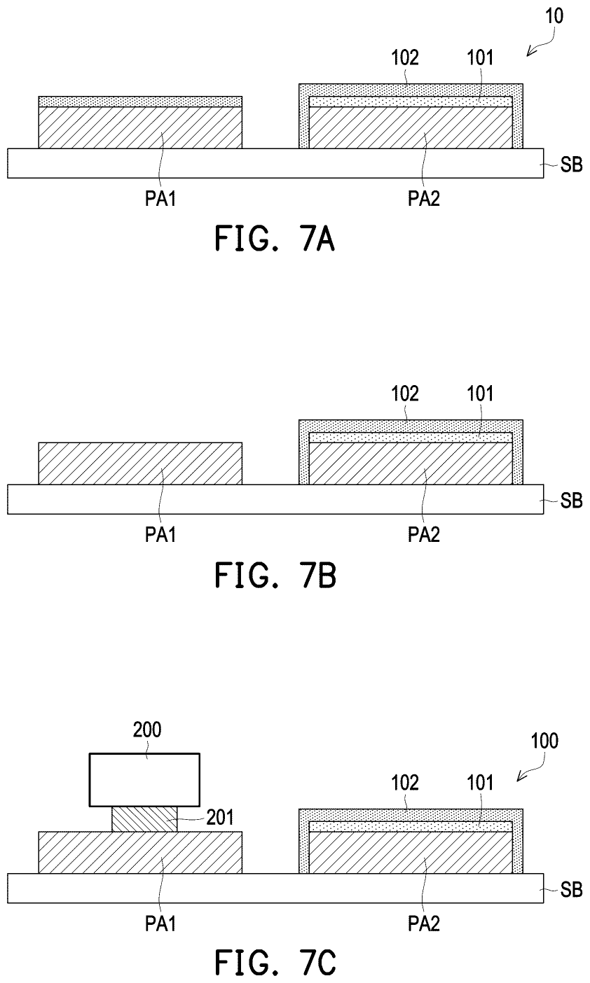

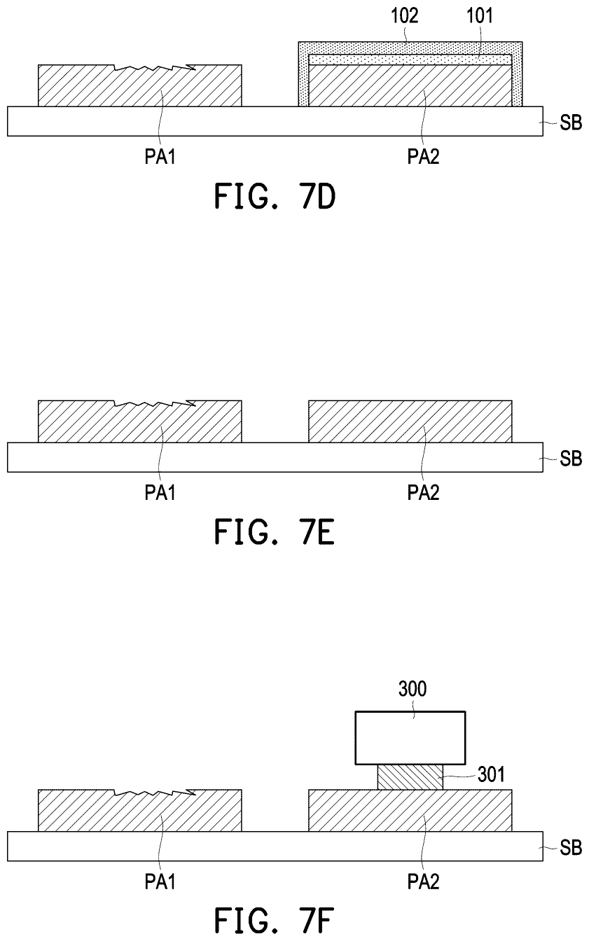

Referring to FIGS. 7A to 7F, FIGS. 7A to 7F illustrate a manufacturing method of the display device shown in FIG. 1D (the third embodiment), FIG. 1E (the fourth embodiment), FIG. 1F (the fifth embodiment), and FIG. 1G (the sixth embodiment) according to an embodiment of the disclosure. It should be noted that the only difference between the embodiment shown in FIGS. 7A to 7F and the embodiment shown in FIGS. 3A to 3F is that in FIGS. 7A to 7F, the first pad PA1 and the second pad PA2 are separate. Therefore, the first pad PA1 and the second pad PA2 shown in FIGS. 7A to 7F may respectively correspond to the pads in the third embodiment, the fourth embodiment, the fifth embodiment, and the sixth embodiment because the pads in these embodiments are separate.

It should further be noted that a corresponding relationship between the first pad PA1 and the second pad PA2 in FIGS. 7A to 7F and each of the pads in FIGS. 1D, 1E, 1F, and 1G is the same as a corresponding relationship described in the embodiment shown in FIGS. 6A to 6F. Therefore, the same details will not be repeated in this embodiment.

As mentioned above, the only difference between the embodiment shown in FIGS. 7A to 7F and the embodiment shown in FIGS. 3A to 3F is that in FIGS. 7A to 7F, the first pad PA1 and the second pad PA2 are separate, while in FIGS. 3A to 3F, the first pad PA1 and the second pad PA2 are integrally formed. Therefore, the process steps and materials of each of the layers shown in FIGS. 7A to 7F are substantially the same as the process steps and materials of each of the layers shown in FIGS. 3A to 3F. Therefore, the same details of the process steps and materials of each of the layers in FIGS. 7A to 7F will not be repeated in the following.

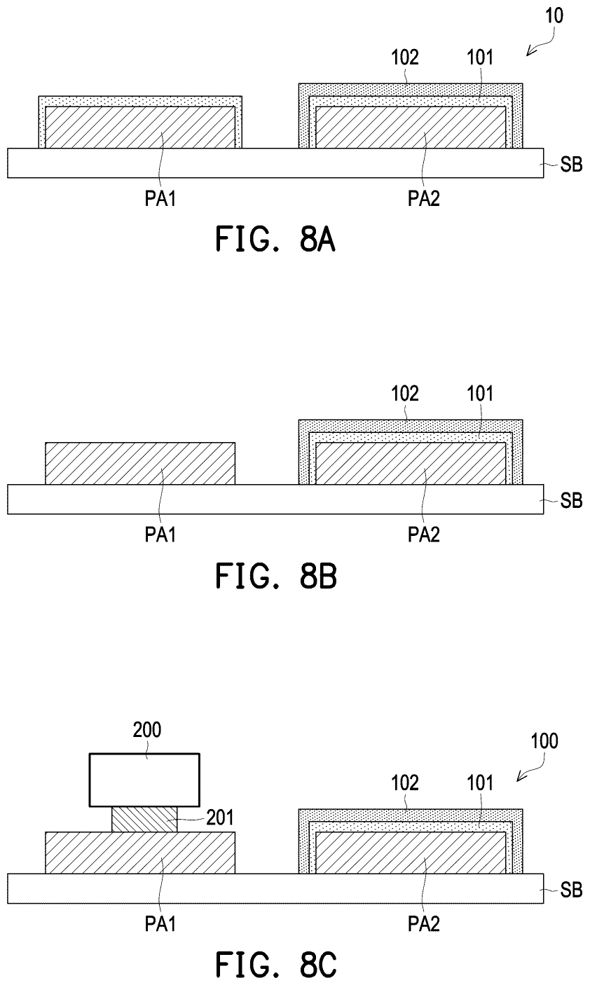

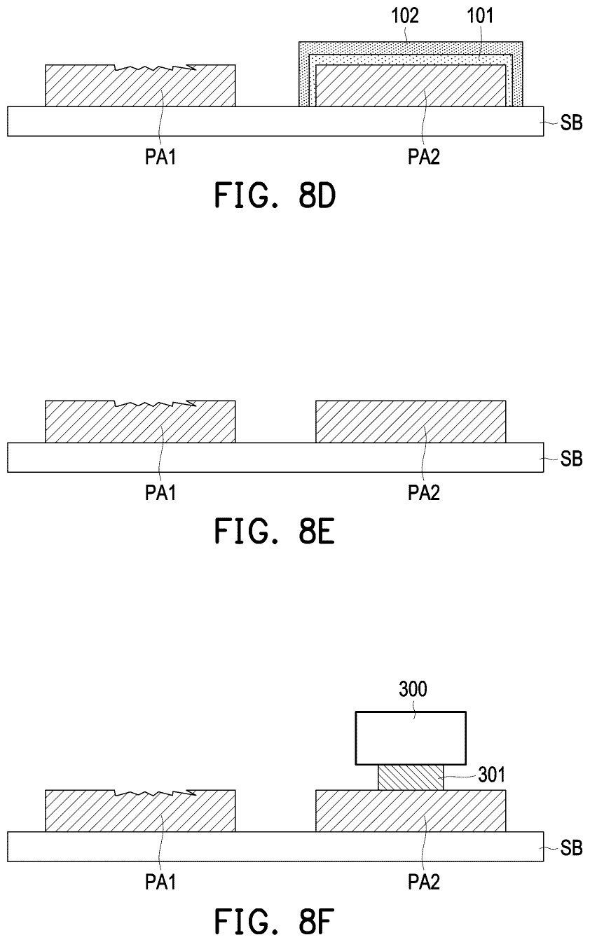

Referring to FIGS. 8A to 8F, FIGS. 8A to 8F illustrate a manufacturing method of the display device shown in FIG. 1D (the third embodiment), FIG. 1E (the fourth embodiment), FIG. 1F (the fifth embodiment), and FIG. 1G (the sixth embodiment) according to an embodiment of the disclosure. It should be noted that the only difference between the embodiment shown in FIGS. 8A to 8F and the embodiment shown in FIGS. 4A to 4F is that in FIGS. 8A to 8F, the first pad PA1 and the second pad PA2 are separate. Therefore, the first pad PA1 and the second pad PA2 shown in FIGS. 8A to 8F may respectively correspond to the pads in the third embodiment, the fourth embodiment, the fifth embodiment, and the sixth embodiment because the pads in these embodiments are separate.

It should further be noted that a corresponding relationship between the first pad PA1 and the second pad PA2 in FIGS. 8A to 8F and each of the pads in FIGS. 1D, 1E, 1F, and 1G is the same as the corresponding relationship described in the embodiment shown in FIGS. 6A to 6F. Therefore, the same details will not be repeated in this embodiment.

As mentioned above, the only difference between the embodiment shown in FIGS. 8A to 8F and the embodiment shown in FIGS. 4A to 4F is that in FIGS. 8A to 8F, the first pad PA1 and the second pad PA2 are separate, while in FIGS. 4A to 4F, the first pad PA1 and the second pad PA2 are integrally formed. Therefore, the process steps and materials of each of the layers shown in FIGS. 8A to 8F are substantially the same as the process steps and materials of each of the layers shown in FIGS. 4A to 4F. Therefore, the same details of the process steps and materials of each of the layers in FIGS. 8A to 8F will not be repeated in the following.

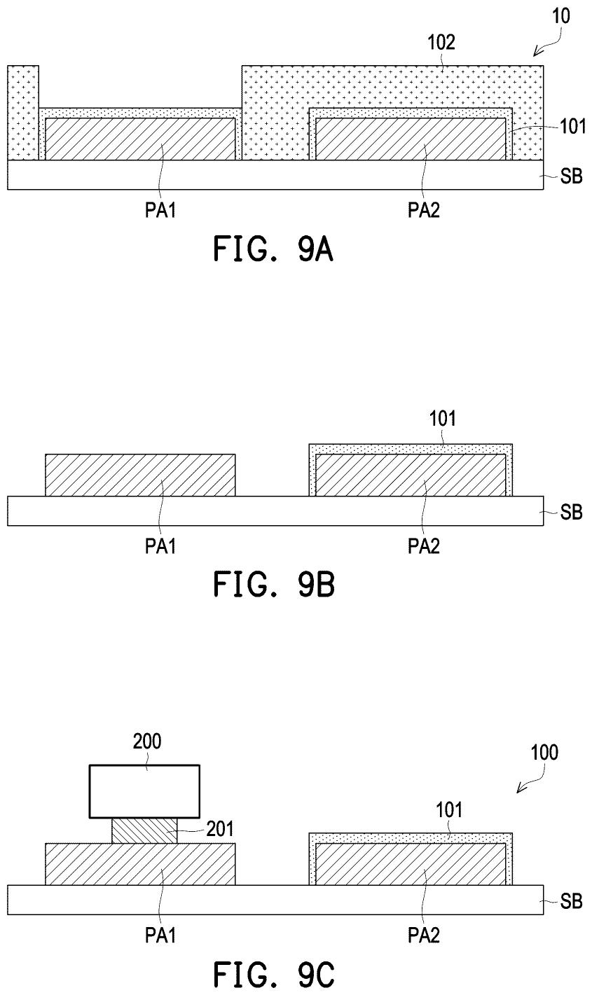

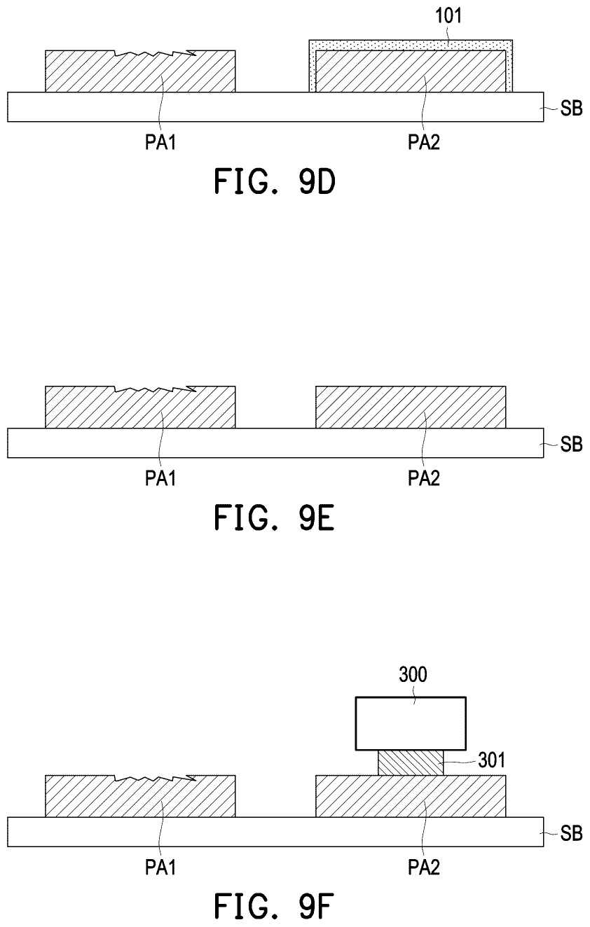

Referring to FIGS. 9A to 9F, FIGS. 9A to 9F illustrate a manufacturing method of the display device shown in FIG. 1D (the third embodiment), FIG. 1E (the fourth embodiment), FIG. 1F (the fifth embodiment), and FIG. 1G (the sixth embodiment) according to an embodiment of the disclosure. It should be noted that the only difference between the embodiment shown in FIGS. 9A to 9F and the embodiment shown in FIGS. 5A to 5F is that in FIGS. 9A to 9F, the first pad PA1 and the second pad PA2 are separate. Therefore, the first pad PA1 and the second pad PA2 shown in FIGS. 9A to 9F may respectively correspond to the pads in the third embodiment, the fourth embodiment, the fifth embodiment, and the sixth embodiment because the pads in these embodiments are separate.

It should further be noted that a corresponding relationship between the first pad PA1 and the second pad PA2 in FIGS. 9A to 9F and each of the pads in FIGS. 1D, 1E, 1F, and 1G is the same as the corresponding relationship described in the embodiment shown in FIGS. 6A to 6F. Therefore, the same details will not be repeated in this embodiment.

As mentioned above, the only difference between the embodiment shown in FIGS. 9A to 9F and the embodiment shown in FIGS. 5A to 5F is that in FIGS. 9A to 9F, the first pad PA1 and the second pad PA2 are separate, while in FIGS. 5A to 5F, the first pad PA1 and the second pad PA2 are integrally formed. Therefore, the process steps and materials of each of the layers shown in FIGS. 9A to 9F are substantially the same as the process steps and materials of each of the layers shown in FIGS. 5A to 5F. Therefore, the same details of the process steps and materials of each of the layers in FIGS. 9A to 9F will not be repeated in the following.

Based on the above, compared to the conventional technology, in the embodiment of the disclosure, the second sub-unit is additionally disposed on the circuit substrate, the pad is disposed on the second sub-unit, and the first protection layer and the second protection layer are disposed on the pad to protect the pad. Accordingly, when the circuit substrate is used to manufacture a display device, and the light emitting diode of the display device is damaged, the pad may be used to dispose another light emitting diode to improve a yield of the display device. The pad is protected by the protection layers to avoid oxidation, and the protection layers may be removed before the pad and the light emitting diode are bonded to improve a bonding yield.

What is claimed is:

1. A circuit substrate, comprising:
a plurality of display units, wherein each of the display units comprises at least one first sub-unit and at least one second sub-unit, each of the at least one first sub-unit comprises at least one first pad, and each of the at least one second sub-unit comprises at least one second pad,
wherein the at least one first pad is provided with a first protection layer, and the at least one second pad is provided with the first protection layer and a second protection layer, wherein the first protection layer is disposed between the at least one second pad and the second protection layer, and
wherein there are spaces suitable for accommodating a light emitting diode above the at least one first pad and the at least one second pad respectively.

2. The circuit substrate according to claim 1, wherein the at least one first pad and the at least one second pad are disposed integrally.

3. The circuit substrate according to claim 1, wherein the at least one first pad and the at least one second pad are disposed separately.

4. The circuit substrate according to claim 1, wherein a number of the at least one first sub-unit of each of the display units is 3, and a number of the at least one second sub-unit of each of the display units is 1.

5. The circuit substrate according to claim 1, wherein a number of the at least one first sub-unit of each of the display units is 3, and a number of the at least one second sub-unit of each of the display units is 3.

6. The circuit substrate according to claim 1, wherein a number of the at least one first pad of each of the at least one first sub-unit is 1, and a number of the at least one second pad of each of the at least one second sub-unit is 1.

7. The circuit substrate according to claim 1, wherein a number of the at least one first pad of each of the at least one first sub-unit is 2, and a number of the at least one second pad of each of the at least one second sub-unit is 2.

8. The circuit substrate according to claim 1, wherein the first protection layer is provided with an insulating layer.

9. The circuit substrate according to claim 1, wherein the first protection layer comprises titanium, molybdenum, a tungsten alloy, a titanium alloy, a molybdenum alloy, nitride of a tungsten alloy, metal nitride, metal oxide and a semiconductor, and the second protection layer comprises metal oxide, and an oxide semiconductor and nitride thereof.

10. The circuit substrate according to claim 1, wherein the first protection layer comprises metal oxide, and an oxide semiconductor and nitride thereof, and the second protection layer comprises an organic photoresist layer.

11. A display device, comprising:
a plurality of display units, wherein each of the display units comprises at least one first sub-unit and at least one second sub-unit, each of the at least one first sub-unit comprises at least one first pad, and each of the at least one second sub-unit comprises at least one second pad,
wherein the at least one second pad is provided with a first protection layer and a second protection layer, wherein the first protection layer is disposed between the at least one second pad and the second protection layer, and the at least one first pad is provided with a light emitting diode, and
wherein there is a space suitable for accommodating the light emitting diode above the at least one second pad.

12. The display device according to claim 11, wherein the at least one first pad and the at least one second pad are disposed integrally.

13. The display device according to claim 11, wherein the at least one first pad and the at least one second pad are disposed separately.

14. The display device according to claim 11, wherein a number of the at least one first sub-unit of each of the display units is 3, and a number of the at least one second sub-unit of each of the display units is 1.

15. The display device according to claim 11, wherein a number of the at least one first sub-unit of each of the display units is 3, and a number of the at least one second sub-unit of each of the display units is 3.

16. The display device according to claim 11, wherein a number of the at least one first pad of each of the at least one first sub-unit is 1, and a number of the at least one second pad of each of the at least one second sub-unit is 1.

17. The display device according to claim 11, wherein a number of the at least one first pad of each of the at least one first sub-unit is 2, and a number of the at least one second pad of each of the at least one second sub-unit is 2.

18. The display device according to claim 11, wherein the at least one first pad is provided with an insulating layer, and the first protection layer is between the at least one first pad and the insulating layer.

19. The display device according to claim 11, wherein the first protection layer comprises titanium, molybdenum, a tungsten alloy, a titanium alloy, a molybdenum alloy, nitride of a tungsten alloy, metal nitride, metal oxide and a semiconductor, and the second protection layer comprises metal oxide, and an oxide semiconductor and nitride thereof.

20. A display device, comprising:
a plurality of display units, wherein each of the display units comprises at least one first sub-unit and at least one second sub-unit, each of the at least one first sub-unit comprises at least one first pad, and each of the at least one second sub-unit comprises at least one second pad,
wherein the at least one second pad is provided with a protection layer, wherein the at least one first pad is provided with a light emitting diode, and
wherein there is a space suitable for accommodating the light emitting diode above the at least one second pad, and the protection layer comprises metal oxide, and an oxide semiconductor and nitride thereof.
